(19) United States
(12) Patent Application Publication
(10) Pub. No.: US 2015/0318274 A1
(43) Pub. Date: Nov. 5, 2015

(54) DEVICE INPUT PROTECTION CIRCUIT

(71) Applicant: Honeywell International Inc., Morristown, NJ (US)

(72) Inventors: Shi Mei Deng, Shanghai (CN); Jie Lv, Shanghai (CN)

(73) Assignee: Honeywell International Inc., Morristown, NJ (US)

(21) Appl. No.: 14/265,600

(22) Filed: Apr. 30, 2014

(51) Int. Cl. H01L 27/02; H02H 5/04; H02H 9/02

(52) U.S. Cl. CPC H01L 27/0288; H02H 9/02; H02H 5/041; H01L 27/0255

(57) ABSTRACT

An input protection circuit for protecting components of an input circuit. The input protection circuit includes a resettable fuse that functions as a current limit integrated circuit to maintain a maximum current so that the circuit can function in a normal operating range with less current. A Zener diode can measure the circuit's voltage and control a metal oxide semiconductor field-effect transistor (MOSEFT) to avoid impact with the analog signal input. The MOSEFT is open if a voltage input is less than a Zener diode breakdown voltage. The Zener diode breakdowns the current flow directly into a ground via the MOSEFT if the voltage input is higher than the Zener diode breakdown voltage. The resettable fuse will shut down until the resettable fuse is reset if the current is higher than the resettable fuse trip current. The protect circuit restarts after the resettable fuse is reset.

### FIELD OF THE INVENTION

Embodiments are generally related to circuits and input signals. Embodiments also relate to power supplies and other circuits, and to protection circuits and components.

### BACKGROUND

An analog input is a measurable electrical signal with a defined range that is typically generated by a sensor and received by a controller. The analog input can vary continuously in a definable manner in relation to a measured property. The analog signals generated by certain types of sensors may require conditioning by conversion to a higher-level standard signal, which is transmitted electronically to the receiving controller.

Analog inputs can be converted to digital signals via an AID (Analog-to-Digital) converter that is usually located at or in association with the controller. Analog input signals can be divided into three basic types of signals: voltage, current, and resistance. In industry control products, for example, a very high frequency may be required to utilize an analog current input and an analog voltage input as a signal input. Such inputs require a very high precision (e.g., 0.1%) at an ambient temperature (e.g., 40° C. to 75° C.).

FIG. 1 illustrates an example schematic diagram of a conventional analog input circuit 100, which is provided without a protection circuit. In the scenario shown in HG. 1, an example, a resistor 110 (e.g., 250 ohm) can be utilized to ground the analog current input circuit 100. The resistor 110 is connected to a switch 108, which in turn is connected to ground. The resistor 110 is also electrically connected to an input 106 and a resistor 116. A capacitor 112 is connected to ground and to resistor 116 and a resistor 118. A capacitor 114 is connected to ground and to resistor 118, which in turn are electrically connected to an A/D converter 120. An output 126 is connected to node 128, which is output from the A/D converter 120 and in turn tied to the negative input of the AID converter 120.

The resistance associated with resistor 110 can result in a voltage with a current input (e.g., 4-20 mA) while an A/D converter 120 can be employed to read the voltage. A key problem associated with such an analog circuit 100 is that when a high power signal (e.g., up to 30V) is mistakenly introduced into the circuit 100, the 250 ohm resistance 110 may be damaged because the resistance's maximum power dissipation is typically less than, for example, 3.6 W (P=U*U/R=30*30/250=3.6 W). Generally, a 0.5 W resistance can be utilized because a 3.6 W resistance results in a very large circuit package so that its maximum current is, for example, 44.7 mA and the voltage is, for example, 11.2V. Such an analog circuit 100 does not limit the voltage and current input signal and may in fact damage the inner circuit.

Based on the foregoing, it is believed that a need exists for an improved protection circuit for protecting input circuits and other components (e.g., power supplies, etc.) by limiting the voltage and current input signal, as will be described in greater detail herein.

### SUMMARY

The following summary is provided to facilitate an understanding of some of the innovative features unique to the disclosed embodiments and is not intended to be a full description. A full appreciation of the various aspects of the embodiments disclosed herein can be gained by taking the entire specification, claims, drawings, and abstract as a whole.

It is, therefore, one aspect of the disclosed embodiments to provide for improved input circuits.

It is another aspect of the disclosed embodiments to provide for an improved protection circuit for protecting an input circuit by limiting the voltage and/or current input signal.

The aforementioned aspects and other objectives and advantages can now be achieved as described herein. An input protection circuit for protecting components of an input circuit is disclosed herein. The protection circuit generally can include a resettable fuse that functions as or assists in providing a current limit integrated circuit to maintain a maximum current so that the input circuit functions in a normal manner with less current. A Zener diode can be included to measure the circuit's voltage and control a metal oxide semiconductor field-effect transistor (MOSEFT) to avoid impact with the signal input. The MOSEFT is open if the voltage input (Vᵢₙ) is less than a Zener diode breakdown voltage. The Zener diode breakdowns the current flow directly into a ground via the MOSEFT if the voltage input (Vᵢₙ) is higher than the Zener diode breakdown voltage. The resettable fuse can shut down until the resettable fuse is reset, if the current is higher than the resettable fuse trip current (e.g., 0.34 A at 23° C.). The protect circuit can restart after the resettable fuse is reset. Such a protection circuit can limit the voltage input and current input of the input circuit and protect the inner circuit components from damage.

### BRIEF DESCRIPTION OF THE FIGURES

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a schematic diagram of a conventional input circuit diagram;

FIG. 2 illustrates a schematic diagram of a device circuit having an input circuit electrically connected to a protection circuit to limit voltage and current input, in accordance with a preferred embodiment;

FIG. 3 illustrates a current-voltage characteristic graph of a Zener diode , in accordance with an embodiment;

FIG. 4 illustrates a current-voltage characteristic graph of a MOSFET, in accordance with an embodiment; and

FIG. 5 illustrates a device circuit having an input power protection device, in accordance with an alternative embodiment.

### DETAILED DESCRIPTION

The particular values and configurations discussed in these non-limiting examples can be varied and are cited merely to illustrate at least one embodiment and are not intended to limit the scope thereof.

The embodiments will now be described more fully hereinafter with reference to the accompanying drawings, in which illustrative embodiments of the invention are shown. The embodiments disclosed herein can be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout. As used herein, the term “and/or” includes any and all combinations of one or more of the associated listed items.

The terminology used herein is for the purpose of describing particular embodiments only and is not intended to be limiting of the invention, As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

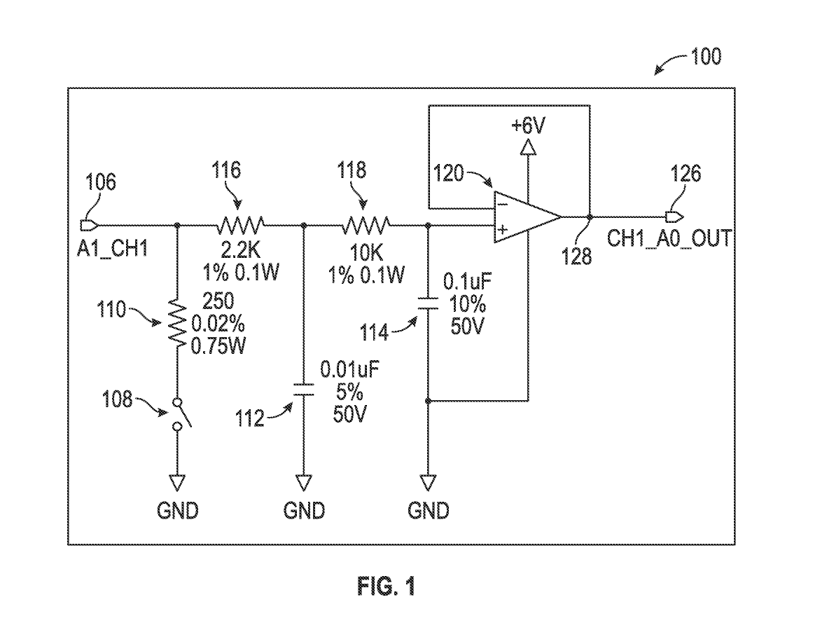

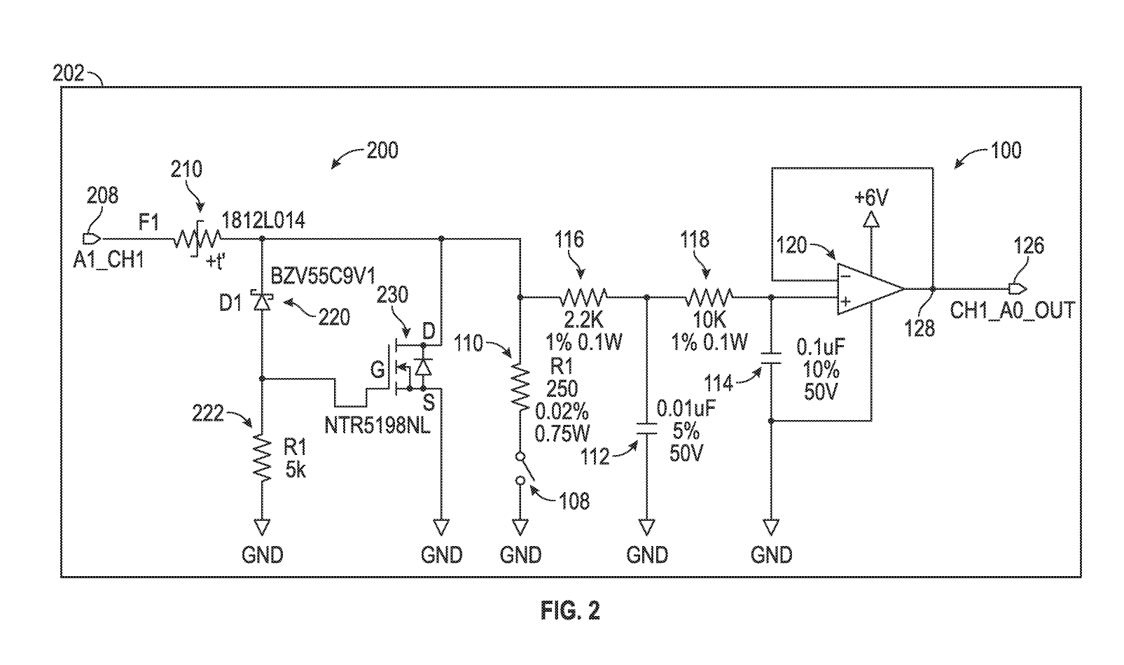

FIG. 2 illustrates a schematic diagram of a device circuit 202 that includes an input circuit 100 electrically connected to a protection circuit 200 to limit voltage and current input, in accordance with a preferred embodiment. Note that in FIGS. 1-4, identical or similar blocks are generally indicated by identical reference numerals. It should be further appreciated than any numerical values shown in such figures (e.g., ohms, resistance, etc.) are provided for illustrative purposes only and are not considered limitations of the disclosed embodiments.

The protection circuit 200, which is connected electronically to the input circuit 100 generally includes an input 208 (which is analogous to the input 106 shown in FIG. 1) that is electronically connected to a polymeric positive temperature coefficient device and/or a resettable fuse 210, which in turn is electrically connected to a Zener diode 220 that in turn is connected to a resistor 222. The fuse 210 is in turn connected to a transistor 230 (e.g., MOSFET) that is in turn connected to ground and to resistor 222. The resistor 222 is also connected to ground. The Zener diode 220, the MOSFET 230, and the fuse 210 are connected to resistors 110 and 116. From this point, the remaining circuit components are similar to those shown in FIG. 1,

The protection circuit 200 protects the resistance associated with resistor 110 from damaging the circuit by preventing the maximum current and voltage from being larger than the functioning resistance (or the defined resistance). The protection circuit 200 can include suitable circuitry and/or other electrical components (e.g., diodes, transistor, etc.) that facilitates the protection of other components of the circuit 100. Thus, it can be appreciated that additional electrical components not shown in FIG. 2 can be added to circuits 100/200, depending upon design considerations. The protection circuit 200 prevents relatively high amplitude signals (e.g., voltage signals, current signals, etc.) from being provided to downstream components (e.g., analog-to-digital converter 120), which may be damaged by such signals.

The protection circuit 200 thus generally includes the polymeric positive temperature coefficient device and/or resettable fuse 210 as the current limit C. The polymeric positive temperature coefficient device (PPTC, commonly known as a resettable fuse, polyfuse or polyswitch) is a passive electronic component, which is capable of being employed to protect against overcurrent faults in electronic circuits. The polymeric PTC device 210, for example, can include a non-conductive crystalline organic polymer matrix that is loaded with carbon black particles to render it conductive. While cool, the polymer is in a crystalline state, with the carbon forced into the regions between crystals, forming many conductive chains. Since the device is conductive (i.e., the “initial resistance”), it can pass a given current, referred to as the “hold current”. If too much current is passed through the device (Le., the “trip current”), the device will begin to heat. As the device 210 heats up, the polymer will expand, changing from a crystalline into anamorphous state.

This expansion separates the carbon particles and breaks the conductive pathways, causing the resistance of the device 210 to increase. This in turn will cause the device 210 to heat faster and expand more, further raising the resistance. This increase in resistance substantially reduces the current in the circuit 100. A small current still flows through the device 210 and is sufficient to maintain the temperature at a level which will keeps the device in a high resistance state. The device 210 can be said to have latching functionality. Note that the PTC 210 can be, for example, a PTC 1812L014 (Littelfuse) component, depending upon design consideration. The PTC 210 provides a maximum hold current of, for example, 0.23 A at −40° C. and 0.06 A at 85° C., so the protection circuit 200 functions fine with less than 0.06 A normally.

The protection circuit 200 circuit can further incorporate a Zener diode 220 to measure the voltage of the circuit 100 and control or allow a power MOSEFT 230 to open or close. The Zener diode 220 can be, for example, a low leakage current Zener diode to avoid impact with the analog signal's input.

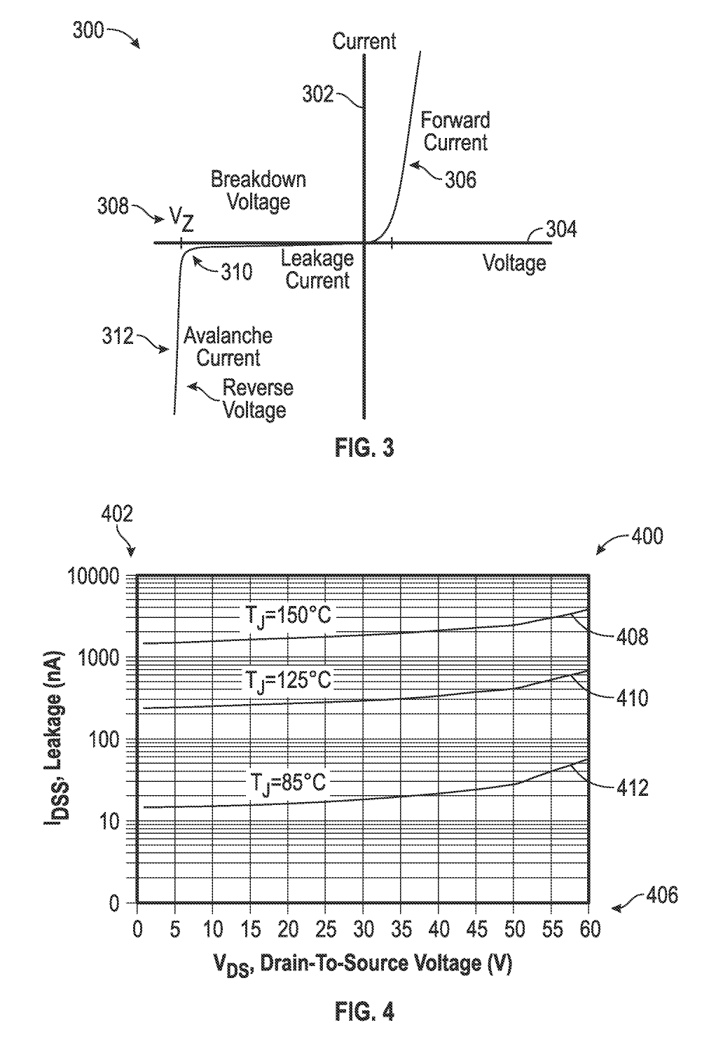

FIG. 3 illustrates an example current-voltage characteristic graph 300 of the Zener diode 220, in accordance with an embodiment. Graph 300 shown in FIG. 3 plots x-axis voltage data 304 versus y-axis current data 302 to produce a curve 306 indicative of forward current, a curve 310 indicative of leakage current, and a curve 312 indicative of avalanche current. Reverse voltage is shown with respect to curve 312 and the breakdown voltage 308 is shown on the x-axis with respect to the leakage current curve 310.

The Zener diode 220 is a diode that allows current to flow in the forward direction in the same manner as an ideal diode, but also permits it to flow in the reverse direction when the voltage is above a certain value known as the breakdown voltage, “Zener knee voltage”, “Zener voltage”, “avalanche point”, or “peak inverse voltage”. Note that one example of Zener diode 220 is a BZV55C9V1 (D1) component having a breakdown voltage of approximately 9.1V normally and a maximum leakage current of approximately 0.5 uA. Such values are indicated herein for illustrative purposes only and are not considered limiting features of the disclosed embodiments.

FIG. 4 illustrates an example current-voltage characteristic graph 400 associated the MOSFET 230, in accordance with an embodiment. The graph 400 plots drain-to-source voltage data 406 on the x-axis versus leakage current data 402 on the y-axis. Representative data is shown in graph 400 with respect to curves 408, 410, and 412,

The metal oxide semiconductor field-effect transistor 230 (MOSFET, MOS-FET, or MOS FET) is a transistor used for amplifying or switching electronic signals. Although the MOSFET is a four-terminal device with source (5), gate (G), drain (D), and body (B) terminals, the body (or substrate) of the MOSFET often is connected to the source terminal, making it a three-terminal device like other field-effect transistors. Because these two terminals are normally connected to each other (short-circuited) internally, only three terminals appear in electrical diagrams. The MOSFET 230 is by far the most common transistor in both digital and analog circuits.

Note that the MOSEFT 230 can be, for example, a low leakage current MOSEFT to avoid impact with the analog signal's input, The MOSEFT 230 can be, for example, NTR5198NL having V_{DSS} is maximum 60V; V_{gs} is maximum ±20V; its maximum DS current is 0.4 W/0.205 Ω≅2 A at 100° C.; and the leakage current is very low (about 20 nA) at 85° C. as shown in FIG. 4. If the voltage input (Vᵢₙ) is less than 9.1V(V_{z}), the Zener diode 220 can't work, so the power MOSEFT 230 is open. If the voltage input (Vᵢₙ) is bigger than 9.1V, the Zener diode 220 will breakdown. The voltage of R₁ can be defined as shown below in equation (1):

V_{R1}−Vᵢₙ−V_{z}

Vgs(Q1)=V_{R1}=Vᵢₙ−V_{z}>VGS(th) (maximum =2.34V) (1)

Then, the MOSEFT 230 can be closed and V_{DS}=0V. The current can flow into the ground by the MOSEFT 230 directly, and it is similar as the Vᵢₙ is short to the power ground. If the current is bigger than the PTC 210 trip current (0.34 A at 23° C.), the PTC 210 will shut down until the PTC 210 is reset. The protect circuit 200 can restart functioning after the PTC 210 is reset to “fine”. The protection circuit 200 limits the voltage input and the current input of the input signal while protecting inner circuit 100 components from damage. The protection circuit 200 is inexpensive to configure and operate because of, for example, the PTZ/Zenor/MOSEFT arrangement.

The protection circuit 200 can be readily adapted to limit the voltage and current input, while also being readily assembled, and resulting in a comparatively low cost of construction The protection circuit 200 protects the components of the inner circuit 100 and avoids the damage caused by conventional configurations.

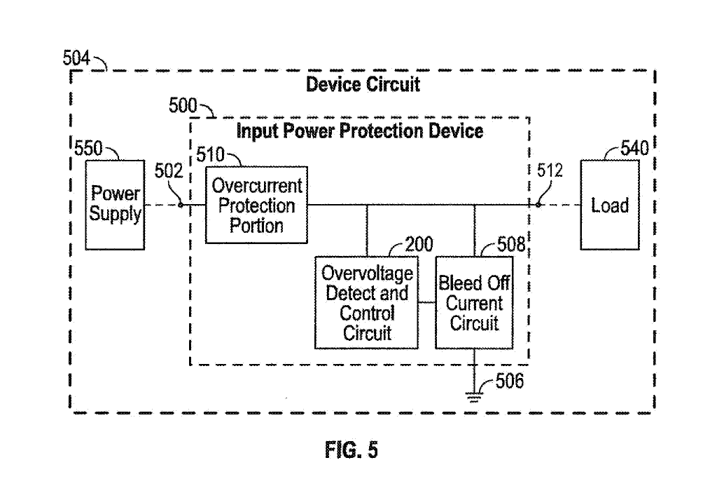

FIG. 5 illustrates a schematic diagram of a device circuit 504 having an input power protection device 500, in accordance with an alternative embodiment. The configuration of device circuit 504 includes a power supply 550 coupled via an input node 502 to an input power protection device 500 which in turn provides output at node 512 to a load 540. The input power protection device 500 generally includes an overcurrent protection portion connected electrically to an overvoltage detection and control circuit 200 and a bleed off current circuit 508, which in turn is connected to ground 506.

Thus, circuit 200 or a variation thereof discussed earlier can be incorporated into the design of the device circuit 504. The significance of FIG. 5 is that the disclosed embodiments can be utilized not just in the context of, for example, analog input circuits, but for the protection of other devices and components such as, for example, powers supplies, and other circuits.

The design shown in FIG. 5 provides a unique solution in which there is no need to control the overcurrent protection portion and auto shut off occurs when the overcurrent occurs. Additionally, such a design only includes an overvoltage detect function, not a real voltage protection circuit. The bleed off current circuit 508 can be employed to bleed off current directly and can incorporate, for example, the MOSFET 110 discussed earlier to short node 512 to ground 506, so that the bleed off current is very large. When the bleed off current circuit 508 functions, the current is increased initially to a very large value because it uses the node output 512 short to ground 506. Then, the current drops to zero and when the current is high rises to an overcurrent value.

Based on the foregoing, it can be appreciated that a number of embodiment, preferred and alternative, are disclosed herein, For example, in one embodiment, an input protection circuit can be implemented, which includes a resettable fuse that acts as a current limit integrated circuit to maintain a maximum current so that the current limit integrated circuit functions in a normal range with less current; and a Zener diode that measures an input circuit voltage and controls a metal oxide semiconductor field-effect transistor to avoid impact with an signal input and thereby limit a voltage input and a current input associated with the input circuit while protecting components of the input circuit from damage.

In another embodiment, the Zener diode can be a low leakage current Zener diode. In yet another embodiment, the metal oxide semiconductor field-effect transistor can be a low leakage current metal oxide semiconductor field-effect transistor, In still another embodiment, the metal oxide semiconductor field-effect transistor is open if a voltage input is less than a Zener diode breakdown voltage. In another embodiment, the Zener diode breakdowns a current flow directly into a ground by the metal oxide semiconductor field-effect transistor if the voltage input is greater than the Zener diode breakdown voltage.

In another embodiment, the resettable fuse can be automatically shut down until the resettable fuse is reset, if the current is larger than a resettable fuse trip current associated with the resettable fuse. In still another embodiment, the protection circuit restarts circuit functioning after the resettable fuse is reset to a fine value. In another embodiment, the Zener diode can be a low leakage current Zener diode and wherein the metal oxide semiconductor field-effect transistor comprises a low leakage current metal oxide semiconductor field-effect transistor.

In yet another embodiment, the Zener diode breakdowns a current flow directly into a ground by the metal oxide semiconductor field-effect transistor if the voltage input is greater than the Zener diode breakdown voltage. In still another embodiment, the resettable fuse can be automatically shut down until the resettable fuse is reset, if the current is larger than a resettable fuse trip current associated with the resettable fuse.

In still another embodiment, an input protection circuit can be provided, which includes a resettable fuse that acts as a current limit integrated circuit to maintain a maximum current so that the current limit integrated circuit functions in a normal range with less current; and a Zener diode that measures an input circuit voltage and controls a metal oxide semiconductor field-effect transistor to avoid impact with a signal input and thereby limits a voltage input and a current input associated with the input circuit while protecting components of the input circuit from damage, wherein the Zener diode comprises a low leakage current Zener diode.

In another embodiment, an analog input protection circuit can be provided, which includes a resettable fuse that acts as a current limit integrated circuit to maintain a maximum current so that the current limit integrated circuit functions in a normal range with less current; and a Zener diode that measures an analog input circuit voltage and controls a metal oxide semiconductor field-effect transistor to avoid impact with an analog signal input and thereby limits a voltage input and a current input associated with the analog input circuit while protecting components of the analog input circuit from damage.

It will be appreciated that variations of the above-disclosed and other features and functions, or alternatives thereof, may be desirably combined into many other different systems or applications. Also, that various presently unforeseen or unanticipated alternatives, modifications, variations or improvements therein may be subsequently made by those skilled in the art which are also intended to be encompassed by the following claims.

1. An input protection circuit, comprising:
a resettable fuse that acts as a current limit integrated circuit to maintain a maximum current so that said current limit integrated circuit functions in a normal range with less current; and
a Zener diode that measures an input circuit voltage and controls a metal oxide semiconductor field-effect transistor to avoid impact with a signal input and thereby limits a voltage input and a current input associated with said input circuit while protecting components of said input circuit from damage.

2. The circuit of claim 1 wherein said Zener diode comprises a low leakage current Zener diode.

3. The circuit of claim 1 wherein said metal oxide semiconductor field-effect transistor comprises a low leakage current metal oxide semiconductor field-effect transistor.

4. The circuit of claim 1 wherein said metal oxide semiconductor field-effect transistor is open if a voltage input is less than a Zener diode breakdown voltage.

5. The circuit of claim 1 wherein said Zener diode breakdowns a current flow directly into a ground by said metal oxide semiconductor field-effect transistor if said voltage input is greater than said Zener diode breakdown voltage.

6. The circuit of claim 1 wherein said resettable fuse is automatically shut down until said resettable fuse is reset if said current is larger than a resettable fuse trip current associated with said resettable fuse.

7. The circuit of claim 6 wherein said protection circuit restarts circuit functioning after said resettable fuse is reset to a fine value.

8. The circuit of claim 1 wherein said Zener diode comprises a low leakage current Zener diode and wherein said metal oxide semiconductor field-effect transistor comprises a low leakage current metal oxide semiconductor field-effect transistor.

9. The circuit of claim 8 wherein said Zener diode breakdowns a current flow directly into a ground by said metal oxide semiconductor field-effect transistor if said voltage input is greater than said Zener diode breakdown voltage.

10. The circuit of claim 8 wherein said resettable fuse is automatically shut down until said resettable fuse is reset if said current is larger than a resettable fuse trip current associated with said resettable fuse.

11. An input protection circuit, comprising:
a resettable fuse that acts as a current limit integrated circuit to maintain a maximum current so that said current limit integrated circuit functions in a normal range with less current; and
a Zener diode that measures an input circuit voltage and controls a metal oxide semiconductor field-effect transistor to avoid impact with a signal input and thereby limits a voltage input and a current input associated with said input circuit while protecting components of said input circuit from damage, wherein said Zener diode comprises a low leakage current Zener diode.

12. The circuit of claim 11 wherein said metal oxide semiconductor field-effect transistor comprises a low leakage current metal oxide semiconductor field-effect transistor.

13. The circuit of claim 11 wherein said metal oxide semiconductor field-effect transistor is open if a voltage input is less than a Zener diode breakdown voltage.

14. An analog input protection circuit, comprising:
a resalable fuse that acts as a current limit integrated circuit to maintain a maximum current so that said current limit integrated circuit functions in a normal range with less current; and
a Zener diode that measures an analog input circuit voltage and controls a metal oxide semiconductor field-effect transistor to avoid impact with an analog signal input and thereby limits a voltage input and a current input associated with said analog input circuit while protecting components of said analog input circuit from damage.

15. The circuit of claim 14 wherein said Zener diode comprises a low leakage current Zener diode.

16. The circuit of claim 14 wherein said metal oxide semiconductor field-effect transistor comprises a low leakage current metal oxide semiconductor field-effect transistor.

17. The circuit of claim 14 wherein said metal oxide semiconductor field-effect transistor is open if a voltage input is less than a Zener diode breakdown voltage.

18. The circuit of claim 14 wherein said Zener diode breakdowns a current flow directly into a ground by said metal oxide semiconductor field-effect transistor if said voltage input is greater than said Zener diode breakdown voltage.

19. The circuit of claim 14 wherein said resettable fuse is automatically shut down until said resettable fuse is reset if said current is larger than a resettable fuse trip current associated with said resettable fuse.

20. The circuit of claim 19 wherein said protection circuit restarts circuit functioning after said resettable fuse is reset to a fine value.
